(19) United States
(12) Patent Application Publication
(10) Pub. No.: US 2007/0069312 A1
(43) Pub. Date: Mar. 29, 2007

(54) Semiconductor device and method for fabricating the same

(76) Inventors: Yoshihiro Satou, Hyogo (JP); Junji Hirase, Osaka (JP)

Correspondence Address: MCDERMOTT WILL & EMERY LLP, 600 13TH STREET, N.W., WASHINGTON, DC, 20005-3096, US

(21) Appl. No.: 11/491,266

(22) Filed: Jul. 24, 2006

(30) Foreign Application Priority Data
Sep. 28, 2005 (JP) 2005-281880

(51) Int. Cl. H01L 29/94

(52) U.S. Cl. 257/412

(57) ABSTRACT

A semiconductor device includes: an isolation region formed in a semiconductor substrate; an active region formed in the semiconductor substrate and surrounded by the isolation region; a fully-silicided gate line formed on the isolation region and the active region; and an insulating sidewall continuously covering a side face of the gate line. At least a portion of the gate line has a projection projecting from the sidewall.

### CROSS-REFERENCE TO RELATED APPLICATION

This application claims priority under 35 U.S.C. §119 on Patent Application No. 2005-281880 filed in Japan on Sep. 28, 2005, the entire contents of which are hereby incorporated by reference.

### BACKGROUND OF THE INVENTION

1. Field of the Invention

The present invention relates to semiconductor devices and methods for fabricating the devices, and particularly to semiconductor devices including fully-silicided gate electrodes and methods for fabricating the devices.

2. Description of the Related Art

With recent increase in the integration degree and speed of semiconductor integrated circuit devices and expansion of the functionality thereof, gate lines formed by combining gate electrodes and interconnects together need to be miniaturized and have their resistance reduced. Therefore, studies using metal materials for the gate lines have been intensively conducted. Examples of such metal materials include metal nitride, dual metal made of two types of pure metals having different work functions and fully-silicided (FUSI) materials formed by changing the entire gate lines into silicide are known. In particular, attention is given on full silicidation as a promising technique because current silicon processing techniques are still used.

Full silicidation of the gate lines reduces the resistance of gate lines, thus increasing the speed of semiconductor devices.

The structures of MOSFETs using such FUSI gates and methods for fabricating the MOSFETs are disclosed in T. Aoyama et al. “IEDM Tech. Digest”, 2004, p.95 and J. A. Kittl et al., “Symp. of VLSI Technology”, 2005, p72.

In microprocessing in which the gate line width is about 45 nm or less, however, the following problems arise even with fully-silicided gate lines.

A first problem is difficulty in making a contact with a gate line. In the case of a fine gate line, the contact area between the gate line and a contact plug is limited by the width of the gate line, so that contact resistance of the contact plug tends to increase. In addition, it is impossible to completely prevent misalignment from occurring during formation of the contact plug. Accordingly, the contact area between the gate and the contact plug further decreases.

To form a sufficient contact area between a gate line and a contact plug, a margin for a given amount of misalignment needs to be provided in designing gate lines. However, it is necessary to keep wide spacing between the gate lines in order to provide such a margin. Therefore, it is difficult to reduce the chip area.

A second problem is that reduction of the gate line width increases the resistance of the gate line even in the case of a fully-silicided gate line, thus causing a delay of operation of the semiconductor device.

### SUMMARY OF THE INVENTION

It is therefore an object of the present invention to provide a semiconductor device in which, in a fully-silicided gate process with a small gate-line width, a sufficient contact area between a gate line and a contact is easily formed and the interconnection resistance of the gate line is reduced without the necessity of a change of design rule of the gate line, and a method for fabricating the semiconductor device.

To achieve the object, according to the present invention, at least a portion of the gate line projects from sidewalls in the semiconductor device.

Specifically, a semiconductor device according to the present invention includes: an isolation region formed in a semiconductor substrate; an active region formed in the semiconductor substrate and surrounded by the isolation region; a fully-silicided gate line formed on the isolation region and the active region; and an insulating sidewall continuously covering a side face of the gate line, wherein at least a portion of the gate line has a projection projecting from the sidewall.

In the semiconductor device of the present invention, at least a portion of the gate line has a projection projecting the sidewall, so that is it possible to connect a fine gate line to a contact through the projection thereof. Accordingly, a sufficient contact area is easily formed between the gate line and the contact, thus reducing the contact resistance between the gate line and the contact. In addition, the cross-sectional area of the gate line increases, so that the interconnection resistance of the gate line decreases. As a result, a high-speed semiconductor device is implemented.

In the semiconductor device, the projection preferably covers at least a portion of an upper face of the sidewall. This structure enables a portion where the gate line and the contact are in contact with each other to have a large width without changing the design rule of the gate line.

The semiconductor device preferably further includes a first contact plug formed on the gate line and electrically connected to the gate line, wherein the gate line projects from the sidewall in a portion where the gate line is connected to the first contact plug. This structure ensures a sufficient contact area between the gate line and the contact plug.

In the semiconductor device, the first contact plug is preferably in contact with a portion of the gate line located on the isolation region.

Preferably, the semiconductor device further includes a gate insulating film formed between the active region and the gate line and a portion of the gate line located on the active region functions as a gate electrode.

The semiconductor device preferably further includes a doped layer formed below both sides of the gate lines in the active region.

Preferably, the semiconductor device further includes a second contact plug formed on the doped layer and electrically connected to the doped layer, and the gate line projects from the sidewall except for at least a portion of the gate line facing the second contact plug. With this structure, a sufficient contact area is formed between the gate line and the contact, the interconnection resistance of the gate line is reduced, and a short circuit between the gate line and the source/drain doped layer is easily prevented.

Preferably, the semiconductor device further includes a silicide layer formed on an upper face of the doped layer and the second contact plug is electrically connected to the doped layer with the silicide layer interposed therebetween.

In the semiconductor device, the gate line preferably projects from the sidewall except for a portion of the gate line located on the active region.

With this structure, it is possible to make the gate line project from the sidewall except for a region where a contact plug connected to the source/drain doped layer can be formed, so that the interconnection resistance of the gate line is reduced with a short circuit prevented from occurring between the source/drain doped layer and the gate line.

In the semiconductor device, the gate line is preferably made of nickel silicide.

A method for fabricating a semiconductor device according to the present invention includes the steps of: (a) forming an active region and an isolation region in a semiconductor substrate such that the active region is surrounded by the isolation region; (b) forming a silicon film and an insulating film in this order over the active region and the isolation region; (c) patterning the silicon film and the insulating film, and then forming an insulating sidewall covering side faces of the silicon film and the insulating film; (d) removing the insulating film after the step (c), thereby exposing an upper surface of the silicon film; (e) forming a metal film covering the silicon film and the sidewall after the step (d); and (f) performing heat treatment on the silicon film and the metal film to fully silicide the silicon film, thereby forming a gate line, wherein in the step (f), a projection projecting from the sidewall is formed in at least a portion of the gate line.

In a method for fabricating a semiconductor device according to the present invention, a projection projecting from the sidewall is formed in at least a portion of the gate line, so that a semiconductor device in which a sufficient contact area is easily formed between a gate line and a contact. In addition, the cross-sectional area of the gate line is increased, so a semiconductor device with a low interconnection resistance of the gate line is implemented.

In the method, the metal film preferably has a thickness equal to or more than 1.1 times the thickness of the silicon film. With this structure, Ni₃Si and Ni₂Si are formed during full silicidation of a silicon film, and projection of the fully-silicided film from the sidewall is ensured.

The method preferably further includes the step (g) of partially etching the silicon film such that the resultant silicon film has a thickness less than half the height of the sidewall, between the steps (d) and (e). With this structure, a portion of the fully-silicided film does not project from the sidewall, so that the possibility of occurrence of a short circuit between the source/drain doped layer and the gate line is reduced.

In this case, in the step (g), only a portion of the silicon film located on the active region is preferably etched. This structure ensures reduction of possibility of a short circuit occurring between the source/drain doped layer and the gate. In addition, a pattern is easily formed.

The method preferably further includes the step of forming, on the semiconductor substrate, a mask prototype film covering the sidewall and the insulating film and planarizing the mask prototype film, thereby forming a mask film for exposing a portion of the sidewall and the insulating film out of the mask prototype film, between the steps of (c) and (d).

The method preferably further includes the step of forming, on the semiconductor substrate, a mask prototype film covering the sidewall and the insulating film and selectively removing the mask prototype film, thereby forming a mask film having a trench in which a portion of the sidewall and the insulating film are exposed out of the mask prototype film, between the steps (c) and (d). With this structure, a portion of the fully-silicided film projecting from the sidewall and extended on the sidewall is allowed to be controlled, so that it is possible to prevent a short circuit from occurring between the fully-silicided film and the doped layer and between adjacent fully-silicided films.

Preferably, the method further includes the step of forming a gate insulating film on the active region before the step (b) and a portion of the gate line located on the active region functions as a gate electrode.

The method preferably further includes the step of forming an interlayer insulating film on the gate line and forming a contact plug electrically connected to the projection of the gate line in the interlayer insulating film, after the step (f).

In the method, the silicon film is preferably one of a polysilicon film and an amorphous silicon film.

In the method, the metal film is preferably a nickel film.

With a semiconductor device and a method for fabricating the device according to the present invention, a sufficient contact area is easily formed between a gate line and a contact and the interconnection resistance of the gate line is reduced without a change of design rule of the gate line in a fully-silicided gate process with a small gate-line width for fabricating a semiconductor device.

### BRIEF DESCRIPTION OF THE DRAWINGS

FIGS. 1A and 1B illustrate a semiconductor device according to a first embodiment of the present invention. FIG. 1A is a plan view and FIG. 1B is a cross-sectional view taken along the line Ib-Ib in FIG. 1A.

FIGS. 2A through 2E are cross-sectional views showing respective process steps of a method for fabricating a semiconductor device according to the first embodiment in the order of fabrication.

FIGS. 3A through 3E are cross-sectional views showing respective process steps of the method for fabricating a semiconductor device according to the first embodiment in the order of fabrication.

FIGS. 4A and 4B are cross-sectional views showing respective process steps of the method for fabricating a semiconductor device according to the first embodiment in the order of fabrication.

FIGS. 5A and 5B illustrate a semiconductor device according to a second embodiment of the present invention. FIG. 5A is a plan view and FIG. 5B is a cross-sectional view taken along the line Vb-Vb in FIG. 5A.

FIGS. 6A through 6D are cross-sectional views showing respective process steps of a method for fabricating a semiconductor device according to the second embodiment in the order of fabrication.

FIGS. 7A through 7D are cross-sectional views showing respective process steps of a method for fabricating a semiconductor device according to a modified example of the second embodiment in the order of fabrication.

FIGS. 8A and 8B illustrate a semiconductor device according to a third embodiment of the present invention. FIG. 8A is a plan view and FIG. 8B is a cross-sectional view taken along the line VIIIb-VIIIb in FIG. 8A.

FIGS. 9A through 9C are cross-sectional views showing respective process steps of a method for fabricating a semiconductor device according to the third embodiment in the order of fabrication.

FIGS. 10A and 10B illustrate a semiconductor device according to a modified example of the third embodiment. FIG. 10A is a plan view and FIG. 10B is a cross-sectional view taken along the line Xb-Xb in FIG. 10A.

### DETAILED DESCRIPTION OF THE INVENTION

### Embodiment 1

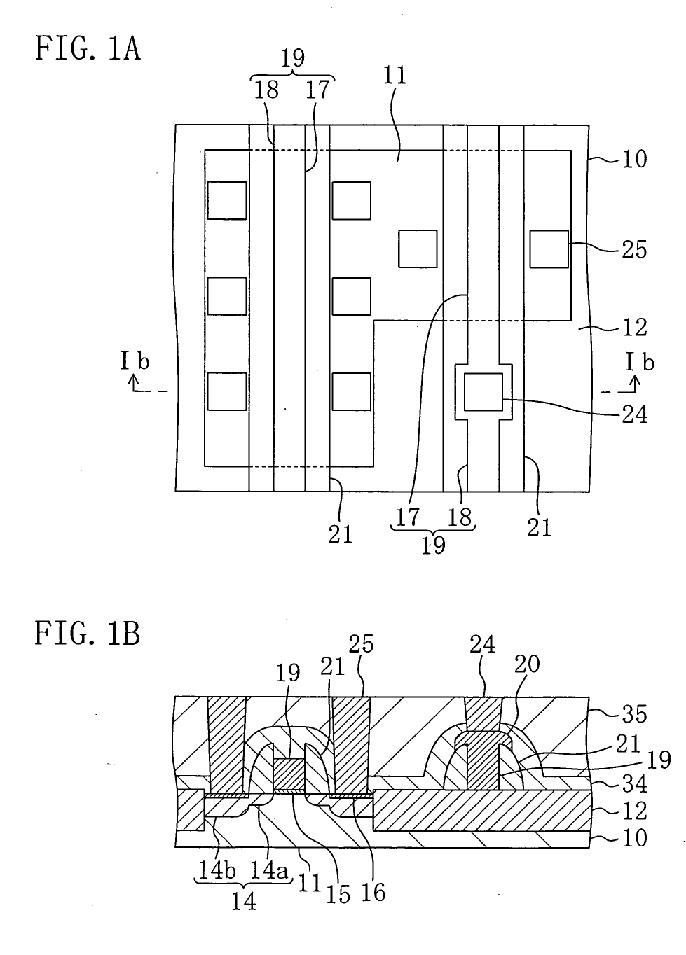

A first embodiment of the present invention will be described with reference to the drawings. FIGS. 1A and 1B illustrate a semiconductor device according to the first embodiment. FIG. 1A is a plan view and FIG. 1B is a cross-sectional view taken along the line Ib-Ib in FIG. 1A.

In the semiconductor device including a metal-insulating film field-effect transistor (MISFET) illustrated in FIGS. 1A and 1B, an active region 11 surrounded by an isolation region 12 is formed in a semiconductor substrate 10. Gate electrodes 17 are formed on the active region 11 and interconnects 18 integrated with the gate electrodes 17 are formed on the isolation region 12. The gate electrodes 17 and the interconnects 18 will be hereinafter correctively referred to as gate lines 19. The gate lines 19 are fully silicided (FUSI) to reduce the resistance thereof. Insulating sidewalls 21 are continuously formed on both sides of the gate lines 19. In FIG. 1A, the boundary between the active region 11 and the isolation region 12 under the gate lines 19 and the sidewalls 21 is represented by broken lines. In this embodiment, two gate lines 19 are formed as an example. Alternatively, the number of gate lines may be changed as necessary.

A source/drain doped layer 14 as a layer where an impurity is diffused is formed below both sides of the gate lines 19 (i.e., the gate electrodes 17) in the active region 11. The source/drain doped layer 14 is constituted by a shallow source/drain doped layer 14a and a deep source/drain doped layer 14b. The upper surface of the deep source/drain doped layer 14b is silicided to form a silicide layer 16. A gate insulating film 15 is formed in the active region 11 under the gate lines 19.

A silicon nitride film 34 is formed over the active region 11 and the isolation region 12 to cover the sidewalls 21 and the gate lines 19. An interlayer insulating film 35 is formed on the silicon nitride film 34. The silicon nitride film 34 can be used as an etch stopper while contact holes are formed in the interlayer insulating film 35. If the silicon nitride film 34 is formed to cause high tensile stress or high compression stress, drivability is enhanced. However, if the effects described above are unnecessary, the silicon nitride film 34 is not necessarily provided.

A first contact plug 24 connected to the gate line 19 and second contact plugs 25 connected to the source/drain doped layer 14 through the silicide layer 16 are formed in the interlayer insulating film 35.

A portion of the gate line 19 in the interface between the first contact plug 24 and the gate line 19 projects from the sidewalls 21 to partially cover the sidewalls 21. Accordingly, the width of the projection 20 that is the portion of the gate line 19 projecting from the sidewalls 21 is larger than the width of the original gate lines. Accordingly, a sufficient contact area is formed between the first contact plug 24 and the gate line 19 even when the first contact plug 24 is misaligned. This prevents the contact resistance of the first contact plug 24 from increasing, so that a high-speed semiconductor integrated circuit device is implemented. On the other hand, since the width of the original gate lines is unchanged, the design rule of the semiconductor device does not need to be changed, so that the area occupied by the semiconductor device does not increase.

The width of the projection 20 of the gate line 19 only needs to be determined in consideration of, for example, the gate width and the size of the first contact plug 24. For example, in a conventional structure with a gate width of 45 nm, if the contact plug has a width of 50 nm, which is a general width, the contact plug cannot be in full contact with the gate line even without any misalignment of the contact plug. This is because the width of the contact plug is larger than that of the gate line. Accordingly, if the contact plug is misaligned, the contact area between the contact plug and the gate line further decreases.

On the other hand, in the structure of the first embodiment, the width of the projection is extended to either side by, for example, 10 nm, so that the portion of the gate line in contact with the contact plug has a width of 65 nm, thus making it possible to obtain a sufficient contact area between the contact plug and the gate line. The width of the projection may be arbitrarily extended as long as problems such as a short circuit with the source/drain doped layer or a short circuit with an adjacent gate line do not occur.

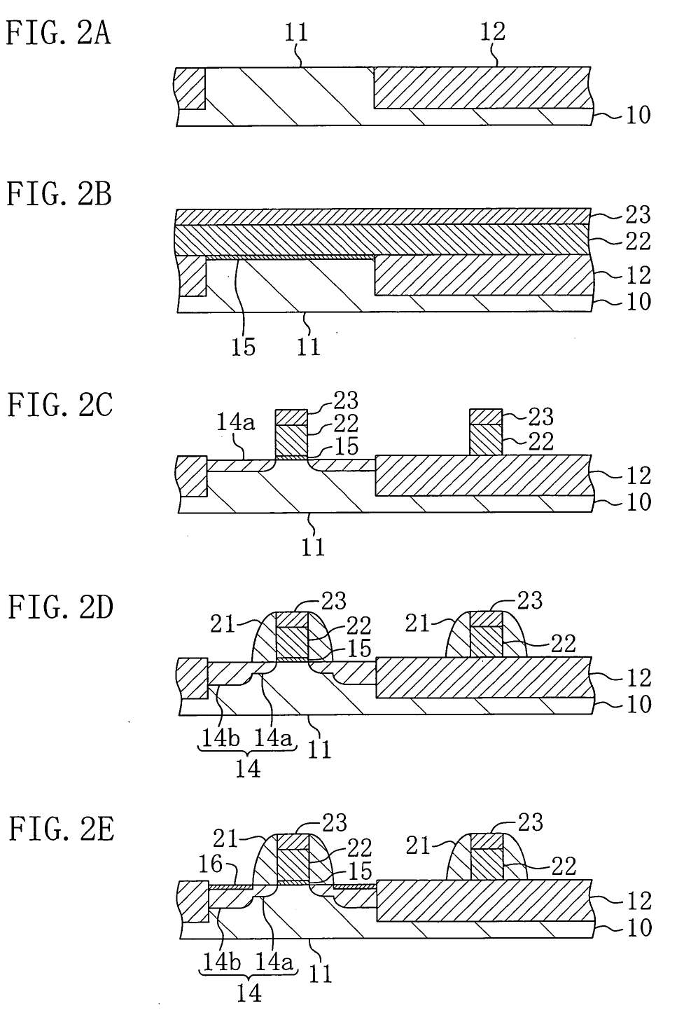

Hereinafter, a method for fabricating a semiconductor device according to the first embodiment will be described with reference to the drawings. FIGS. 2A through 2E to FIGS. 4A and 4B show cross-sectional structures in respective process steps of the method for fabricating a semiconductor device of this embodiment in the order of fabrication. FIGS. 2A through 2E to FIGS. 4A and 4B show cross sections taken along the line Ib-Ib in FIG. 1A.

First, as illustrated in FIG. 2A, an isolation region 12 for electrically isolating devices is formed in an upper portion of a semiconductor substrate 10 by, for example, an STI (shallow trench isolation) method. An active region 11 surrounded by the isolation region 12 is formed in the semiconductor substrate 10. Then, ions are implanted in the substrate 10, thereby forming wells (not shown). At this time, a p-well is formed in an nMISFET region and an n-well is formed in a pMISFET region.

Next, as illustrated in FIG. 2B, the upper surface of the active region 11 is oxidized by, for example, dry oxidation, wet oxidation or oxidation using oxygen radicals, thereby forming a gate insulating film 15 having a thickness of about 2 nm and made of silicon oxide. Subsequently, a polysilicon film 22 to be gate lines is formed by, for example, chemical vapor deposition (CVD) to a thickness of 80 nm over the gate insulating film 15 and the isolation region 12. Thereafter, a silicon oxide film 23 is formed by, for example, CVD to a thickness of 60 nm over the polysilicon film 22. The thickness of the silicon oxide film 23 is less than that of the polysilicon film 22. In this manner, the height of sidewalls 21, which will be formed in a subsequent process step, is less than twice the thickness of the polysilicon film 22.

Thereafter, as illustrated in FIG. 2C, the silicon oxide film 23 is patterned by photolithography and dry etching into the shape of gate electrodes. Subsequently, using the patterned silicon oxide film 23 as a mask, dry etching is performed on the polysilicon film 22 and the gate insulating film 15. Thereafter, a shallow source/drain doped layer 14a is formed by ion implantation below the sides of the polysilicon film 22 in the active region.

Subsequently, as illustrated in FIG. 2D, a silicon nitride film is deposited by, for example, CVD to a thickness of 50 nm over the entire surface of the semiconductor substrate 10, and then the deposited silicon nitride film is subjected to anisotropic etching, thereby forming sidewalls 21 on the side faces of the polysilicon film 22 and the silicon oxide film 23. Subsequently, through photolithography, ion implantation and heat treatment for activating the implanted impurity, a deep source/drain doped layer 14b is formed below both sides of the polysilicon film 22 in the active region.

Then, as illustrated in FIG. 2E, a natural oxide film is removed from the surface of the deep source/drain doped layer 14b. Then, a nickel film is deposited by, for example, sputtering to a thickness of 10 nm over the semiconductor substrate 10. Subsequently, first rapid thermal annealing (RTA) is performed on the semiconductor substrate 10 at 320° C. in a nitrogen atmosphere, so that a reaction occurs between silicon forming the semiconductor substrate 10 and the nickel film in contact with silicon, thereby forming nickel suicide. Thereafter, the semiconductor substrate 10 is immersed in a solution in which hydrochloric acid and a hydrogen peroxide solution, for example, are mixed, thereby selectively removing unreacted nickel remaining on, for example, the isolation region 12, the silicon oxide film 23 and the sidewalls 21. Then, second RTA is performed on the semiconductor substrate 10 at a temperature (e.g., 550° C.) higher than that of the first RTA. In this manner, a silicide layer 16 having low resistance is formed in the surface of the deep source/drain doped layer 14b.

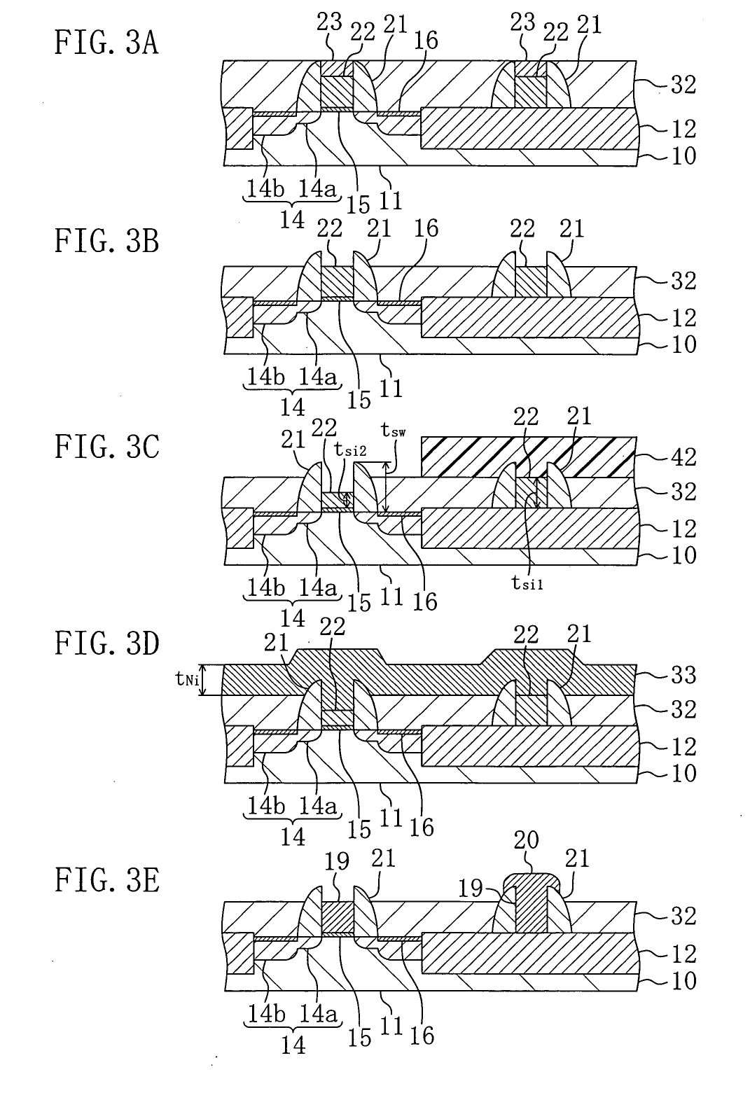

Thereafter, as illustrated in FIG. 3A, a silicon oxide film 32 serving as a mask during full silicidation is formed on the semiconductor substrate 10. Then, the surface of the silicon oxide film 32 is planarized by CMP. This planalization stops at the upper ends of the sidewalls 21 and the silicon oxide film 23.

Subsequently, as illustrated in FIG. 3B, with dry etching or wet etching performed under conditions having selectivity with respect to the silicon nitride film, the silicon oxide film 23 and the silicon oxide film 32 are etched until the polysilicon film 22 is exposed. At this time, the silicon oxide film 32 is not necessarily etched.

Then, as illustrated in FIG. 3C, a resist pattern 42 is formed on the silicon oxide film 32 to cover the polysilicon film 22 and the sidewalls 21 in a region in which a first contact plug 24 is to be formed. Subsequently, with dry etching or wet etching performed under conditions having selectivity with respect to the silicon nitride film and the silicon oxide film, the polysilicon film 22 is etched by 40 nm except for the region where the first contact plug 24 is to be formed. The amount of the etched portion of the polysilicon film 22 is adjusted such that the thickness t_{Si2} of the polysilicon film 22 after etching is less than half the height t_{sw} of the sidewalls 21.

Thereafter, as illustrated in FIG. 3D, the resist pattern 42 is removed, and then a metal film 33 made of nickel is deposited by sputtering to a thickness of 100 nm over the silicon oxide film 32 to cover the sidewalls 21 and the polysilicon film 22. Then, RTA is performed on the semiconductor substrate 10 at 400° C. in a nitrogen atmosphere, so that a reaction occurs between the polysilicon film 22 and the metal film 33, thereby fully siliciding the polysilicon film 22. The thickness t_{Ni} of the metal film 33 is 1.1 times or more the thickness of the polysilicon film 22 in the region where the first contact plug 24 is to be formed.

Subsequently, as illustrated in FIG. 3E, the unreacted metal film 33 is removed, thereby forming gate lines 19 having a projection 20 projecting from the sidewalls 21 in the region where the first contact plug 24 is to be formed.

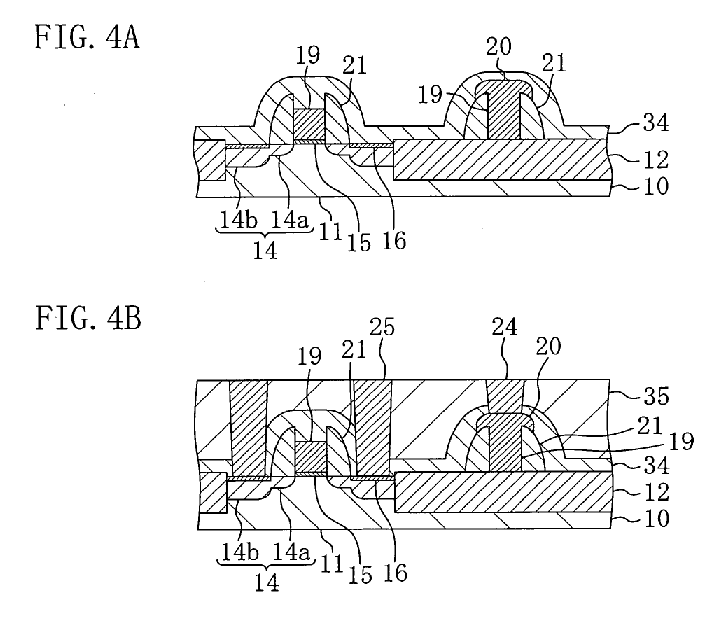

Thereafter, as illustrated in FIG. 4A, the silicon oxide film 32 is removed, and then the silicon nitride film 34 is deposited by, for example, CVD to a thickness of 50 nm over the semiconductor substrate 10. Then, an interlayer insulating film 35 is formed by, for example, CVD over the silicon nitride film 34. The silicon nitride film 34 only needs to be formed when necessary. In a case where the silicon nitride film 34 is not formed, an interlayer insulating film 35 may be deposited over the silicon oxide film 32 without etching of the silicon oxide film 32.

Then, as illustrated in FIG. 4B, a resist mask pattern (not shown) is formed on the interlayer insulating film 35. Then, with dry etching, a contact hole reaching the projection 20 of the gate line 19 and contact holes reaching the silicide layer 16 on the source/drain doped layer 14 are formed. Subsequently, tungsten is buried in the contact holes by, for example, CVD, thereby forming a first contact plug 24 and second contact plugs 25.

As described above, in this embodiment, silicidation is performed in a state in which the polysilicon film 22 in the region where the first contact plug 24 is formed is thicker than that in the other region.

Specifically, in this embodiment, the thickness t_{Si1} of the polysilicon film 22 is 80 nm in the region where the first contact plug 24 is formed. The thickness t_{Ni} of the metal film 33 is 100 nm and equal to or more than 1.1 times the thickness t_{Si1} of the polysilicon film 22. Under such a condition in which a nickel content is higher than a polysilicon content, Ni₂Si and Ni₃Si are formed during silicidation, so that the thickness of the fully-silicided film obtained by fully siliciding the polysilicon film 22 is about twice the thickness t_{Si1} of the polysilicon film 22.

On the other hand, the height t_{sw} of the sidewalls 21 is 140 nm, which is the sum of the thickness of the polysilicon film 22 and the thickness of the silicon oxide film 23, because the thickness of the gate insulating film 15 is small enough to be negligible. Accordingly, the thickness t_{Si1} of the polysilicon film 22 is equal to or more than half the height t_{sw} of the sidewalls 21. As a result, the fully-silicided film obtained by fully siliciding the polysilicon film 22 projects from the sidewalls 21 in the region where the first contact plug 24 is formed. In addition, the projection also extends laterally, so that the upper surface of the sidewalls 21 is partially covered.

In the region other than the region where the first contact plug 24 is formed, the thickness of the polysilicon film 22 is reduced by etching. Accordingly, the thickness t_{Si2} of the polysilicon film 22 in this portion is 40 nm, and thus is less than half the height t_{sw} of the sidewalls 21. Therefore, in this region, the polysilicon film 22 does not project from the sidewalls 21 even after full silicidation.

As described above, in the region where the gate line 19 projects from the sidewalls 21, the thickness of the polysilicon film 22 is equal to or more than half the height of the sidewalls 21 and the thickness of the metal film 33 is equal to or more than 1.1 times the thickness of the polysilicon film 22. On the other hand, in the region where the gate line 19 does not project from the sidewalls 21, the thickness of the polysilicon film 22 only needs to be less than half the height of the sidewalls.

### Embodiment 2

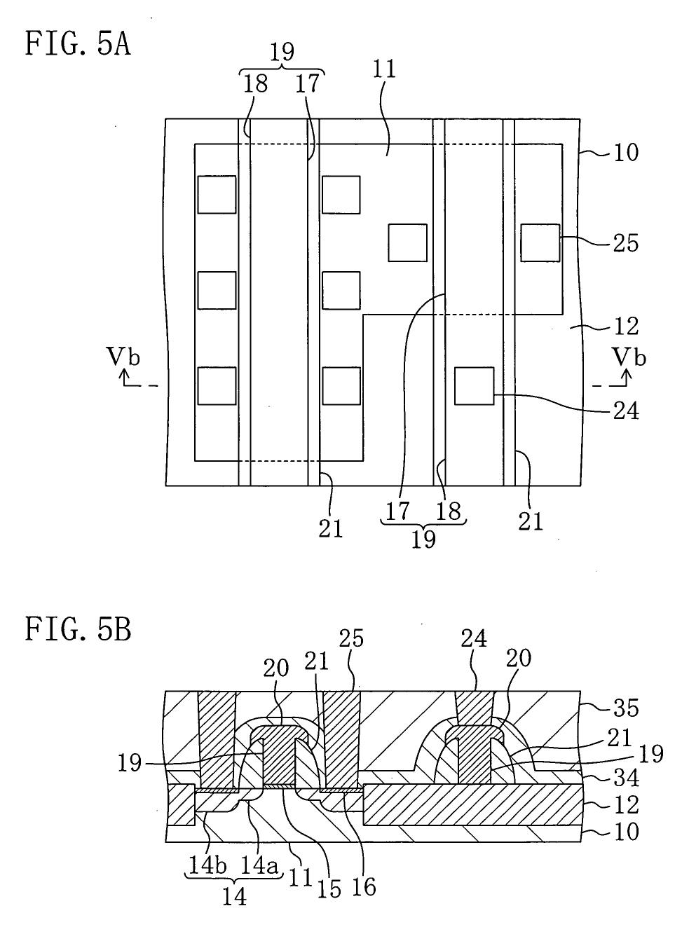

Hereinafter, a second embodiment of the present invention will be described with reference to the drawings. FIGS. SA and 5B illustrate a semiconductor device according to the second embodiment. FIG. 5A is a plan view and FIG. 5B is a cross-sectional view taken along the line Vb-Vb in FIG. 5A.

As illustrated in FIGS. 5A and 5B, a semiconductor device including a MISFET of this embodiment is different from the semiconductor device of the first embodiment only in that all the gate lines 19 have projections 20. The other aspects of the second embodiment are the same as those in the first embodiment. Providing all the gate lines 19 with the projections 20 not only makes it easy to obtain a sufficient contact area between the gate lines and the contact plugs but also increases the cross-sectional area of the gate lines 19, as compared to a conventional semiconductor device. Accordingly, the resistance of the gate lines 19 is reduced, and a high-speed semiconductor integrated circuit device is implemented.

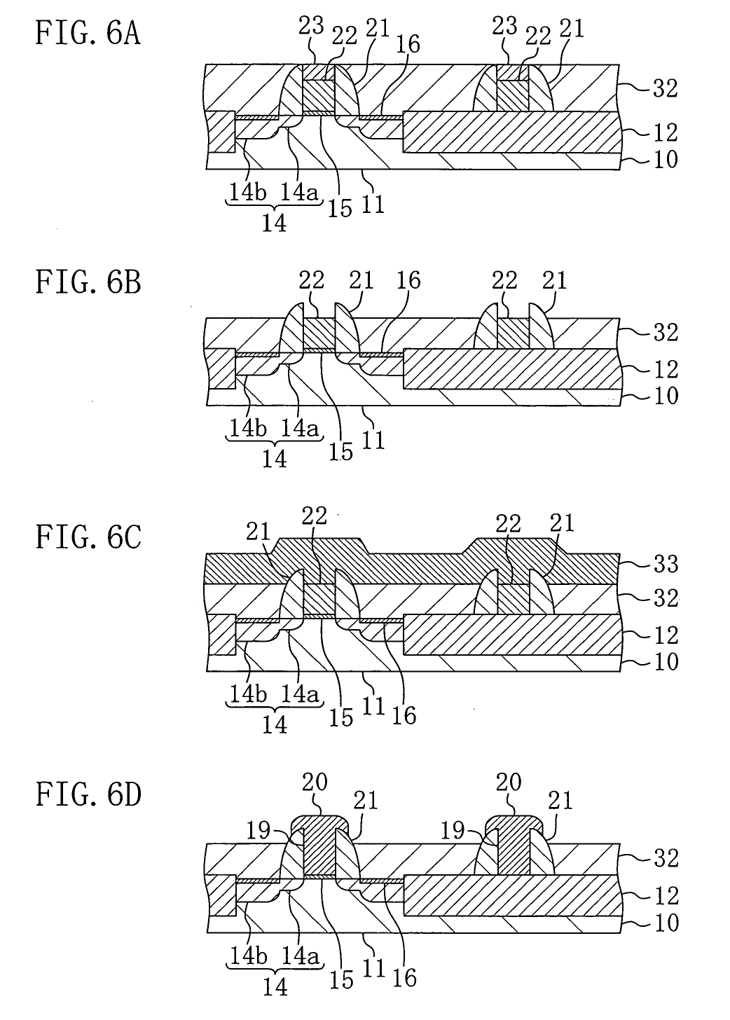

Hereafter, a method for fabricating a semiconductor device according to this embodiment will be described with reference to the drawings. FIGS. 6A through 6D show cross-sectional structures in respective process steps of a method for fabricating a semiconductor device according to this embodiment in the order of fabrication. FIGS. 6A through 6D show cross sections taken along the line Vb-Vb in FIG. 5A. Process steps up to formation of a silicon oxide film 32 covering sidewalls 21 on a semiconductor substrate 10 are the same as those in the first embodiment, and thus description thereof will be omitted.

As illustrated in FIG. 6A, a silicon oxide film 32 is formed on the semiconductor substrate 10. Then, the surface of the silicon oxide film 32 is planarized by CMP. This planarization stops at the upper ends of the sidewalls 21 and a silicon oxide film 23.

Next, as illustrated in FIG. 6B, with dry etching or wet etching performed under conditions having selectivity with respect to the silicon nitride film, the silicon oxide film 23 and the silicon oxide film 32 are etched until the polysilicon film 22 is exposed. At this time, the silicon oxide film 32 is not necessarily etched.

Then, in this embodiment, as illustrated in FIG. 6C, a metal film 33 made of, for example, nickel is deposited by sputtering to a thickness of 100 nm over the silicon oxide film 32 to cover the sidewalls 21 and the polysilicon film 22 without etching of the polysilicon film 22.

Subsequently, RTA is performed on the semiconductor substrate 10 at, for example, 400° C. in a nitrogen atmosphere, so that a reaction occurs between the polysilicon film 22 and the metal film 33, thereby fully siliciding the polysilicon film 22.

Thereafter, as illustrated in FIG. 6D, the unreacted metal film 33 is removed, thereby obtaining gate lines 19 made of the silicided film having projections 20 that project from the sidewalls 21 and partially cover the sidewalls 21.

The subsequent process steps are the same as those described in the first embodiment, and thus description thereof will be omitted.

As described above, with the method for fabricating a semiconductor device of the second embodiment, the thickness of the polysilicon film 22 is equal to or larger than half the height of the sidewalls 21 so that the polysilicon film 22 is fully silicided. Accordingly, all the gate lines 19 have projections 20 projecting from the sidewalls 21. This not only makes it easy to obtain a sufficient contact area between the first contact plug 24 and the gate lines 19 but also increases the cross-sectional area of the gate lines 19. Accordingly, the resistance of the gate lines 19 is reduced. As a result, a high-speed semiconductor integrated circuit device is implemented.

### Modified Example of Embodiment 2

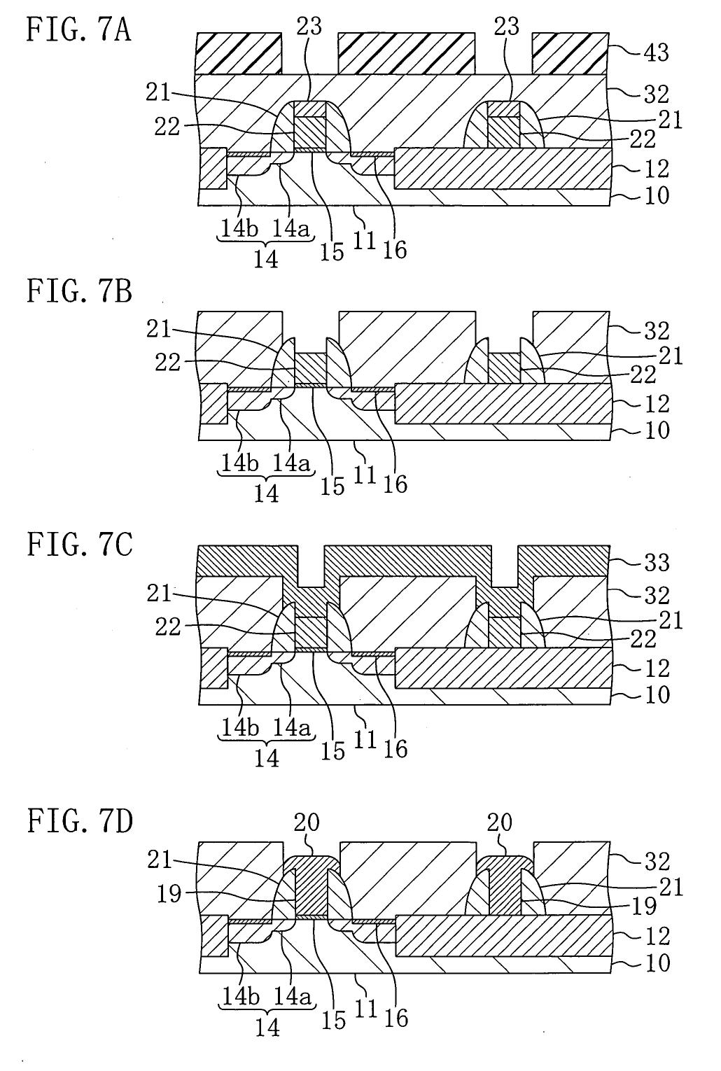

Hereinafter, a modified example of the second embodiment will be described with reference to the drawings. FIGS. 7A through 7D show cross-sectional structures in respective process steps of a method for fabricating a semiconductor device according to this modified example of the second embodiment in the order of fabrication. Process steps up to formation of a silicide layer 16 in the surface of a deep source/drain doped layer 14b are the same as those in the first embodiment, and thus description thereof will be omitted.

As illustrated in FIG. 7A, a silicon oxide film 32 to serve as a mask during full silicidation is formed on a semiconductor substrate 10, and then the surface of the silicon oxide film 32 is planarized by CMP. At this time, unlike the second embodiment shown in FIG. 6A, the planarization is performed such that the silicon oxide film 32 remains on the sidewalls 21 and the silicon oxide film 23. Subsequently, a resist pattern 43 having openings over the silicon oxide film 23 is formed on the silicon oxide film 32.

Next, as illustrated in FIG. 7B, with dry etching performed under conditions having selectivity with respect to the silicon nitride film and the polysilicon film, the silicon oxide film 32 and the silicon oxide film 23 are etched using the resist pattern 43 (not shown) as a mask. In this manner, trenches in which the upper surface of the polysilicon film 22 and the upper surface of portions of the sidewalls 21 are exposed are formed in the silicon oxide film 32, and then the resist pattern 43 is removed.

Thereafter, as illustrated in FIG. 7C, a metal film 33 made of nickel is deposited by, for example, sputtering to a thickness of 100 nm over the silicon oxide film 32 to cover the sidewalls 21 and the polysilicon film 22. Then, RTA is performed on the semiconductor substrate 10 at 400° C. in a nitrogen atmosphere, so that a reaction occurs between the polysilicon film 22 and the metal film 33, thereby forming a fully-silicided film.

Subsequently, as illustrated in FIG. 7D, the unreacted metal film 33 is removed. In this manner, a semiconductor device including gate lines 19 formed out of the fully-silicided film having projections 20 projecting from the sidewalls 21 and partially covering the sidewalls 21 is obtained.

In this modified example, the trenches in which only portions of the sidewalls 21 are exposed are formed and full silicidation is performed in these trenches. Accordingly, the region in which the projections 20 extend on the sidewalls 21 is limited within the width of the trenches. As a result, in addition to the advantages of the second embodiment, an advantage that a short circuit between gate lines are prevented even when the gate lines are arranged with a narrow pitch is obtained.

This modified example is applicable to the method for fabricating a semiconductor device of the first embodiment.

### Embodiment 3

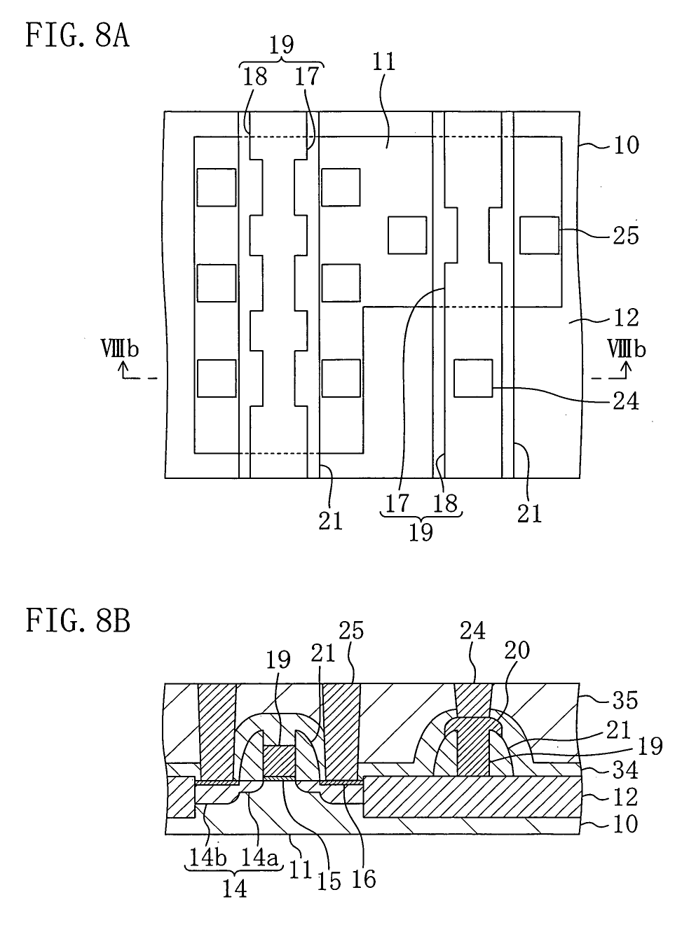

Hereinafter, a third embodiment of the present invention will be described with reference to the drawings. FIGS. 8A and 8B illustrate a semiconductor device according to the third embodiment. FIG. 8A is a plan view and FIG. 8B is a cross-sectional view taken along the line VIlIb-VIlIb in FIG. 8A. In FIGS. 8A and 8B, components also shown in FIG. 1 are denoted by the same reference numerals, and thus description thereof will be omitted.

As illustrated in FIG. 8A and 8B, in the semiconductor device of this embodiment, a gate line 19 does not project from sidewalls 21 near second contact plugs 25 electrically connected to a source/drain doped layer 14. To reduce the chip area of the semiconductor device, the second contact plugs connected to the source/drain doped layer need to be located as close as possible to the gate electrode. In this case, if the gate line 19 extends on the sidewalls 21, a short circuit might occur between the gate line 19 and the second contact plugs 25. In view of this, in this embodiment, the gate line 19 does not project from the sidewalls 21 near the second contact plugs 25 so as to prevent the gate line 19 from extending on the sidewalls 21. However, the gate line 19 projects from the sidewalls 21 in the other region, so that the advantage of reduction of interconnection resistance of the gate lines 19 is sufficiently obtained.

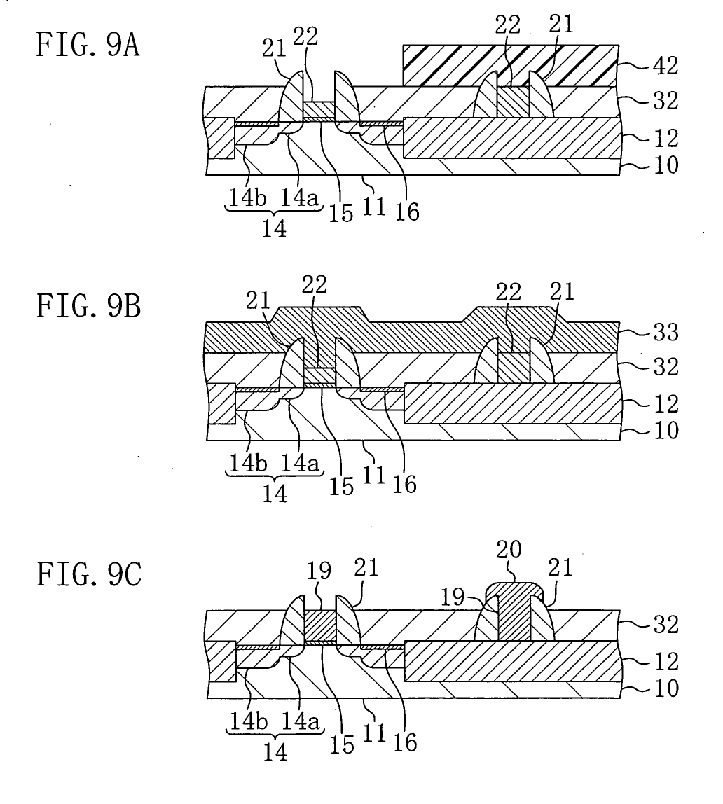

Hereinafter, a method for fabricating a semiconductor device according to this embodiment will be described with reference to the drawings. FIGS. 9A through 9C show cross-sectional structures in respective process steps of the method for fabricating a semiconductor device of the third embodiment in the order of fabrication. Process steps after formation of a silicon oxide film 32 covering sidewalls 21 up to exposure of a polysilicon film 22 are the same as those in the first embodiment, and thus description thereof will be omitted.

After the polysilicon film 22 is exposed, as illustrated in FIG. 9A, a resist pattern 42 is formed on the silicon oxide film 32 to cover the polysilicon film 22 and the sidewalls 21 except for a region where second contact plugs 25 are to be formed on an active region 11. In this embodiment, “except for the region where the second contact plugs 25 are to be formed on the active region 11” means the region excluding the region where the second contact plugs 25 are to be formed in the gate length direction (including a margin for alignment of the second contact plugs 25). Subsequently, with dry etching or wet etching performed under conditions having selectivity with respect to the silicon nitride film and the silicon oxide film, the polysilicon film 22 is etched by 40 nm near the region where the second contact plugs 25 are to be formed.

Next, as illustrated in FIG. 9B, the resist pattern 42 is removed, and then a metal film 33 made of nickel is deposited by sputtering to a thickness of 100 nm over the silicon oxide film 32 to cover the sidewalls 21 and the polysilicon film 22. Thereafter, RTA is performed on the semiconductor substrate 10 at 400° C. in a nitrogen atmosphere, so that a reaction occurs between the polysilicon film 22 and the metal film 33, thereby fully siliciding the polysilicon film 22.

Subsequently, as illustrated in FIG. 9C, the unreacted metal film 33 is removed, so that a gate line 19 not projecting from the sidewalls 21 is formed near a region on the active region 11 where the second contact plugs 25 are to be formed in the gate length direction and a gate line 19 projecting from the sidewalls 21 is formed on the isolation region 12 and on a region of the active region 11 where the second contact plugs 25 are not formed in the gate length direction. Accordingly, as illustrated in FIG. 8A, the width in the gate length direction of the gate line 19 located between the second contact plugs 25 is less than the width in the gate length direction of the gate lines 19 in the other region.

The subsequent process steps are the same as those described in the first embodiment, and thus description thereof will be omitted.

As described above, in this embodiment, the thickness of the polysilicon film 22 is reduced and then silicidation is performed near the region where the second contact plugs 25 are to be formed. Accordingly, the gate line 19 does not project from the sidewalls 21 near the second contact plugs 25. As a result, a short circuit is less likely to occur between the second contact plugs 25 and the gate lines 19. On the other hand, in the region other than the region near the second contact plugs 25, the gate line 19 projects from the sidewalls 21, so that the cross-sectional area of the gate line 19 is increased, thereby reducing the resistance of the gate lines.

In this embodiment, the thickness of the polysilicon film 22 is 40 nm near the second contact plugs 25 and is 80 nm in the other regions. However, the thickness of the polysilicon film 22 may be changed as necessary, in consideration of the height of the sidewalls, for example. The region where the gate line 19 does not project from the sidewalls 21 needs to be at least a region where the gate line 19 and the second contact plugs 25 face each other.

As described in the modified example of the second embodiment, in this embodiment, trenches in which the polysilicon film 22 and portions of the sidewalls 21 are exposed may be formed so that the polysilicon film 22 is fully silicided.

### Modified Example of Embodiment 3

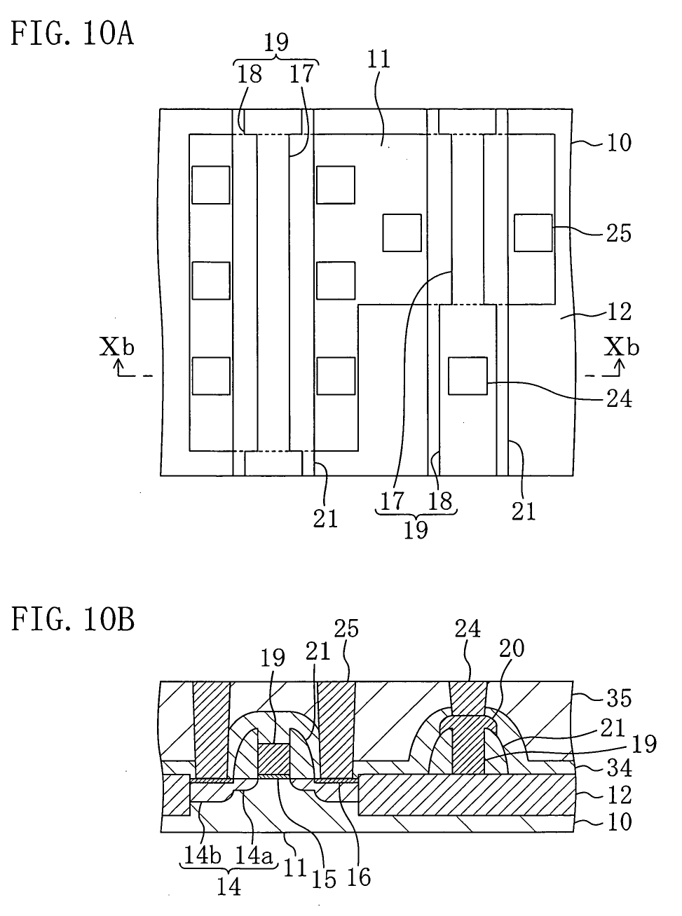

Hereinafter, a modified example of the third embodiment will be described with reference to the drawings. FIGS. 10A and 10B illustrate a semiconductor device according to the modified example of the third embodiment. FIG. 10A is a plan view and FIG. 10B is a cross-sectional view taken along the line Xb-Xb in FIG. 10A.

As illustrated in FIGS. 10A and 10B, in the semiconductor device of this modified example, a gate line 19 formed on an active region 11 does not project from sidewalls 21 and only a gate line 19 formed on an isolation region 12 projects from sidewalls 21.

In this manner, on the active region 11 where second contact plugs 25 can be formed, the gate line 19 does not project from the sidewalls 21, so that occurrence of a short circuit between the gate line 19 and the second contact plugs 25 is prevented. In addition, the structure in which the gate line 19 does not project from the sidewalls 21 on the entire active region 11 eases formation of a mask pattern.

In the foregoing embodiments and the modified examples thereof, the fully-silicided film is formed out of the polysilicon film. Alternatively, the fully-silicided film may be made of another semiconductor material containing amorphous silicon or silicon. In the foregoing description, nickel is used as a metal for full silicidation. Alternatively, the metal for full silicidation may be replaced by another metal such as platinum. The silicide layer 16 is not necessarily formed by using nickel but may be formed by using another metal for silicidation such as cobalt, titanium or tungsten. The sidewalls 21 are not necessarily made of a silicon nitride film and may be made of a stack of a silicon oxide film and a silicon nitride film.

As described above, a semiconductor device and a method for fabricating the device according to the present invention has an advantage in which in a semiconductor device using a fully-silicided gate process with a small gate line width, sufficient contact areas are easily obtained between gate lines and contacts and the interconnection resistance of the gate lines is low without a change of design rule of the gate lines. The present invention is useful for a semiconductor device including a fully-silicided gate electrode and a method for fabricating the device.

What is claimed is:

1. A semiconductor device, comprising:
an isolation region formed in a semiconductor substrate;
an active region formed in the semiconductor substrate and surrounded by the isolation region;
a fully-silicided gate line formed on the isolation region and the active region; and
an insulating sidewall continuously covering a side face of the gate line,
wherein at least a portion of the gate line has a projection projecting from the sidewall.

2. The semiconductor device of claim 1, wherein the projection covers at least a portion of an upper face of the sidewall.

3. The semiconductor device of claim 1, further comprising a first contact plug formed on the gate line and electrically connected to the gate line,
wherein the gate line projects from the sidewall in a portion where the gate line is connected to the first contact plug.

4. The semiconductor device of claim 3, wherein the first contact plug is in contact with a portion of the gate line located on the isolation region.

5. The semiconductor device of claim 1, further comprising a gate insulating film formed between the active region and the gate line,
wherein a portion of the gate line located on the active region functions as a gate electrode.

6. The semiconductor device of claim 5, further comprising a doped layer formed below both sides of the gate lines in the active region.

7. The semiconductor device of claim 6, further comprising a second contact plug formed on the doped layer and electrically connected to the doped layer,
wherein the gate line projects from the sidewall except for at least a portion of the gate line facing the second contact plug.

8. The semiconductor device of claim 7, further comprising a silicide layer formed on an upper face of the doped layer,
wherein the second contact plug is electrically connected to the doped layer with the silicide layer interposed therebetween.

9. The semiconductor device of claim 1, wherein the gate line projects from the sidewall except for a portion of the gate line located on the active region.

10. The semiconductor device of claim 1, wherein the gate line is made of nickel silicide.

11. A method for fabricating a semiconductor device, comprising the steps of:
(a) forming an active region and an isolation region in a semiconductor substrate such that the active region is surrounded by the isolation region;
(b) forming a silicon film and an insulating film in this order over the active region and the isolation region;
(c) patterning the silicon film and the insulating film, and then forming an insulating sidewall covering side faces of the silicon film and the insulating film;
(d) removing the insulating film after the step (c), thereby exposing an upper surface of the silicon film;
(e) forming a metal film covering the silicon film and the sidewall after the step (d); and
(f) performing heat treatment on the silicon film and the metal film to fully silicide the silicon film, thereby forming a gate line,
wherein in the step (f), a projection projecting from the sidewall is formed in at least a portion of the gate line.

12. The method of claim 11, wherein the metal film has a thickness equal to or more than 1.1 times the thickness of the silicon film.

13. The method of claim 11, further comprising the step (g) of partially etching the silicon film such that the resultant silicon film has a thickness less than half the height of the sidewall, between the steps (d) and (e).

14. The method of claim 13, wherein in the step (g), only a portion of the silicon film located on the active region is etched.

15. The method of claim 11, further comprising the step of forming, on the semiconductor substrate, a mask prototype film covering the sidewall and the insulating film and planarizing the mask prototype film, thereby forming a mask film for exposing a portion of the sidewall and the insulating film out of the prototype mask film, between the steps of (c) and (d).

16. The method of claim 11, further comprising the step of forming, on the semiconductor substrate, a mask prototype film covering the sidewall and the insulating film and selectively removing the mask prototype film, thereby forming a mask film having a trench in which a portion of the sidewall and the insulating film are exposed out of the mask prototype film, between the steps (c) and (d).

17. The method of claim 11, further comprising the step of forming a gate insulating film on the active region before the step (b),
wherein a portion of the gate line located on the active region functions as a gate electrode.

18. The method of claim 11, further comprising the step of forming an interlayer insulating film on the gate line and forming a contact plug electrically connected to the projection of the gate line in the interlayer insulating film, after the step (f).

19. The method of claim 11, wherein the silicon film is one of a polysilicon film and an amorphous silicon film.

20. The method of claim 11, wherein the metal film is a nickel film.
